(19) United States
(12) Patent Application Publication
(10) Pub. No.: US 2015/0236639 A1
(43) Pub. Date: Aug. 20, 2015

(54) SOLAR RECEIVER MODULE FOR A CONCENTRATED PHOTOVOLTAIC (CPV) POWER PLANT

(71) Applicant: COMMISSARIAT A L'ENERGIE ATOMIQUE ET AUX ENERGIES ALTERNATIVES, Paris (FR)

(72) Inventors: Christophe Mangeant, Yenne (FR); Gatien Fleury, Greoux-les-Bains (FR)

(21) Appl. No.: 14/428,451

(22) PCT Filed: Aug. 28, 2013
(86) PCT No.: PCT/IB2013/058078

§ 371 Date: Mar. 16, 2015

(30) Foreign Application Priority Data
Sep. 14, 2012 (FR) 1258653

(51) Int. Cl. H02S 20/32; H01L 31/054; G02B 7/02; H02S 40/22; G02B 3/08

(52) U.S. Cl. CPC H02S 20/32; H02S 40/22; H01L 31/0543; G02B 3/08; G02B 7/028

(57) ABSTRACT

The invention relates to a solar receiver module for a concentrated photovoltaic (CPV) power plant, comprising a first optic, referred to as primary optic, consisting of a Fresnel lens, at least one second optic, referred to as secondary optic, having a straight frusto-conical shape or straight frusto-pyramidal shape, arranged below the primary optic, at least one photovoltaic cell arranged below a secondary optic, in order to receive the solar rays concentrated by the primary optic and said secondary optic, the receiver module also including temperature sensors for measuring temperature differences between a reference temperature and at least four points regularly distributed around the axis connecting the centre of the bases of the frustum of the cone or pyramid of a secondary optic, in order to produce a thermal cartography of same.

### TECHNICAL FIELD

The present invention relates to the field of solar collectors for concentrated photovoltaic (CPV) solar plants.

The present invention more particularly relates to production of a novel solar collector module that enables better tracking of the sun both in its elevation and azimuth angles relative to the Earth, in order to make the photovoltaic cells making up the module operate as close as possible to their maximum electrical power point.

The invention also relates to a method for controlling a corresponding CPV solar plant.

### PRIOR ART

At the present time, photovoltaic systems connected to the mains grid generate a broad spectrum of powers, from a few hundred watts peak (Wp) for residential applications to a few tens of MWp for large terrestrial plants.

In these systems, CPV technologies are increasingly pervasive. These CPV technologies use lenses to concentrate light on photovoltaic cells. In order to generate electrical powers that are useable by industrial grids, it is necessary to place many photovoltaic cells in series, this enabling high voltages, typically about 1000 V, to be obtained.

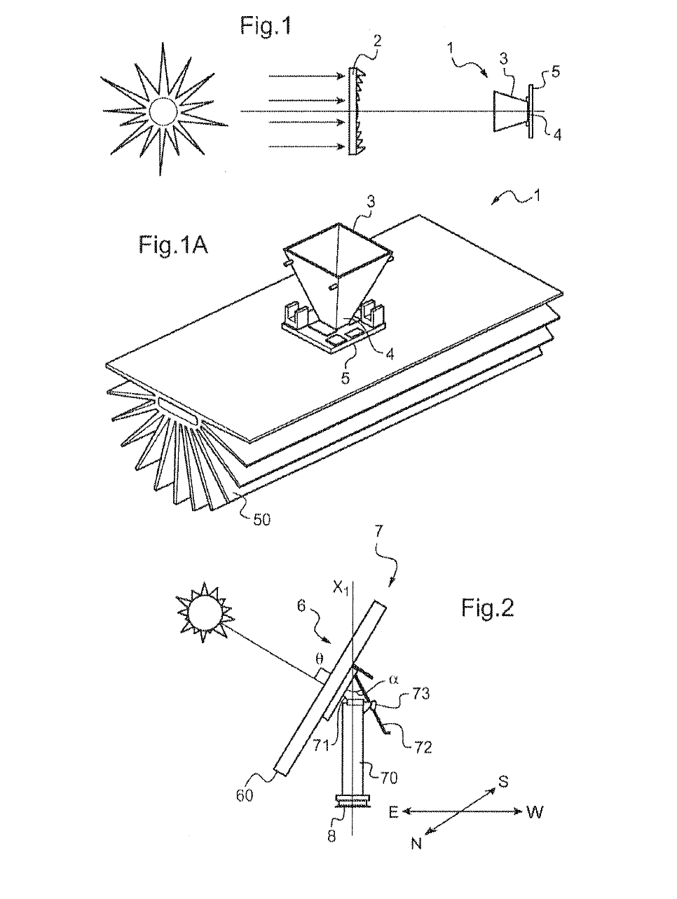

More precisely, a solar collector module implementing this type of CPV technology essentially comprises four main components, namely a primary lens, a secondary lens, a photovoltaic cell and a heat sink. FIGS. 1 and 1A schematically show such a collector module 1. It comprises, from the exterior to the interior, respectively, a primary lens 2 consisting of a Fresnel lens; a secondary lens 3 arranged below the Fresnel lens; a photovoltaic cell 4 arranged in the zone of concentration of rays from the sun by the Fresnel lens 2, said cell being assembled on a collector 5 that especially comprises an electrical insulator, cell adhesives, a bypass diode having a safety function and input/output connectors; and lastly, a heat sink 50 arranged below the collector 5. The secondary lens 3 is right-frustopyramidal shaped and may be made either of a reflective material such as aluminum (solid aluminum or aluminum taking the form of a deposited thin film), or of glass, the reflection in this case being achieved via the refractive index difference between air and the glass. Thus, as may be seen in FIGS. 1 and 1A, the energy of the sun is concentrated on the center of the pyramid (secondary lens 3) by way of the primary lens 2, the secondary lens 3 thus redirecting light that is poorly focused onto the photovoltaic cell 4. The function of the primary lens 2 is to concentrate rays from the sun incident orthogonal to its surface on the photovoltaic cell 4, whereas the secondary lens merely recovers some of the photons that are poorly focused by the primary lens 2. In other words, the main function of the secondary lens 3 is to optimize performance by enabling better spatial distribution of the incident energy: it allows performance to be improved and the uniformity of the flux of light onto the photovoltaic cell 4 to be increased. The latter then generates DC current via the photovoltaic effect.

Thus, each of the components 2, 3, 4, 5 and 50 plays a paramount role and allows the performance of such systems to be increased, whether in terms of raw performance (in the laboratory) or in terms of power generation (under actual operating conditions). Among the main particularities of these CPV technologies, mention may especially be made of:
a high sensitivity to the incident solar spectrum due to the solar cell technology used;
an optimal focal distance between the lenses and the photovoltaic cell dependent on the solar spectrum; and
a clear need to dissipate heat, due to the use of a light-concentrating system.

Three generations of photovoltaic cells are currently commercially available:
cells based on silicon Si (single-crystal silicon or polysilicon) that have photo-conversion efficiencies, also called quantum efficiencies, i.e. levels of conversion of solar energy into electrical power, lower than 25%, especially due to limitations specific to the material itself: specifically, silicon intrinsically has a bandgap that does not allow a very broad spectrum of photons to be captured;
cells formed by thin films of cadmium telluride CdTe or by thin films based on copper, indium, gallium selenide (CIGS), which have lower photo-conversion efficiencies but that may be produced at relatively low cost; and
multi junction cells, most of the time triple junction cells, also known as III-V cells, made from semiconductor materials such as Ge, InGaAs and InGaP, which allow very high photoconversion efficiencies, higher than 40%, to be achieved, but that are expensive to produce.

Mention may also be made of the very low-cost cells made of organic materials (polymers) that are in the process of becoming available, even though, for the time being, these cells have very low photoconversion efficiencies, typically lower than 12%.

One of the decisive parameters affecting the choice of a given photovoltaic cell technology is the cost price of a kilowatt hour (kWh). As mentioned above, although they have high photoconversion efficiencies, multi junction cells are expensive.

Optical concentrating systems allow the area of such multi junction cells required to generate a given amount of electricity to be considerably decreased, and therefore the cost price of an electrical kWh to be decreased. This is why solar collector modules implementing CPV technology incorporate optical concentrating systems. Two main optical concentrating systems are currently used: those incorporating Fresnel lenses, as shown in FIG. 1, and those incorporating dish reflectors. It is thus advantageously possible to use multi junction cell unit areas of 1 to 2 cm² with optical system areas of about 500 to 2000 cm². In other words, in practice it is possible to obtain solar energy concentration factors comprised between 500 and 1500. For example, the solar collector modules referred to as high-concentrated photovoltaic (HCPV) modules may use optical systems concentrating more than 500 suns on multi junction cells of 1 cm². It will be noted here that, conventionally, the photovoltaic industry uses the term high-concentrated HCPV when the concentration ratio of a CPV collector module is more than 400 suns.

Because the Earth has an elliptical orbit about the sun, it is essential to ensure that the primary lens and the rays from the sun are as perpendicular as possible throughout the day whatever the season, in order to ensure optimal direct illumination of the cells, as is ideally depicted in FIG. 1. Moreover, the higher the concentration factor, the higher the precision of the orientation toward the sun of a solar collector comprising a plurality of collector modules must be. Typically, for a solar concentration factor equal to 500, it is in general considered the case that the collector must be oriented with a precision higher than 1°.

Thus, it is necessary to mount CPV solar collectors on an orientable supporting means, called a tracker, the role of which is therefore to adjust the orientation of the CPV modules to track the trajectory of the sun relative to the Earth, i.e. to ensure, with a very high precision, the perpendicularity between the primary concentrating lens and the rays from the sun.

FIG. 2 schematically shows a solar collector 6 incorporating a plurality of CPV modules on a supporting structure 60, usually called a rack, mounted on what is referred to as a “two-axis” solar tracker 7. The tracker 7 must thus track the trajectory of the sun throughout the day in its azimuth angle θ, which defines its orientation south/north and east/west, and in its elevation angle α, which defines a position in the sky relative to the horizontal. It will be noted that, as symbolized by the arrows E, W, S and N, south is into the page, whereas the east is to the left of the page. The tracker 7 comprises a central supporting means 70 fastened to a base 8, for example a foundation made of concrete and located on the Earth's surface. The solar collector 6 is mounted on the supporting means 70 so as to be able to pivot about two axes, including a pivot axis 71 about which it is made to pivot by way of a screw/nut system 72, 73. In the perfect tracking position, as shown in FIG. 2, the primary lenses of the solar collector 6 are oriented perpendicularly to the rays from the sun. In order to track the trajectory of the sun in its azimuth angle, an orientating mechanism with an actuator is controlled in order to rotate the rack 60 of the collector 6 about the longitudinal axis X1 of the central supporting means 70 of the tracker. To track the trajectory of the sun in its elevation angle (angle α in FIG. 2), an orientating mechanism with an actuator is controlled to move the screw 72 translationally in its nut 73, thereby causing the rack 60 to rotate about the pivot point 71.

The tracking of the sun, i.e. the control of the movement of the tracker to track the trajectory of the sun both in its azimuth and elevation angles, is conventionally achieved by implementing one of the following methods, which may, if required, be combined:
methods using astronomical calculations based on ephemerides coupled with a kinematic model of the orientating mechanisms of the tracker;
methods using astronomical calculations coupled with feedback of the movements via one or more optomechanical sensors, such as an optical square and/or video camera; and
methods using astronomical calculations coupled with verification by a photovoltaic sensor separate from the cells of the CPV modules and the collimation of which is ensured by virtue of a collimating device the function of which is to ensure that only parallel rays originating from the sun reach the photovoltaic cell.

Patent applications US 2010/0018519A1, US 2010/0018518A1 and US 2010/023138 A1 also describe another method in which the average electrical power generated by a given CPV solar collector is measured to determine the error, if any, in the position of the tracker. This method is relatively resource intensive to implement and statistical treatment of the generated electrical power is required, i.e. a sizeable number of measurements are required in order to factor out climactic variables that may affect the results of the method.

U.S. Pat. No. 7,795,568 B2 also describes another tracking method, employing open-loop adjustment, in which the desired position is estimated by a kinematic model alone, and in which the precision of the adjustment, and therefore the correct alignment of the CPV collector relative to the sun, is not monitored. Thus, this tracking method must be supplemented with routine verification of the correct alignment of the CPV collector relative to the trajectory of the sun.

Patent application US 2010/0108860 A1 discloses such a routine verification of the position of the CPV collector. However, this routine verification is complicated since it requires the CPV collector to be physically rotated/moved for the verification as such.

Apart from the mentioned drawbacks of the prior-art methods described above, the intrinsic sensitivity of all the measurement sensors used and possible variations in the dimensions and assembly of the components of a CPV module mean that in fact known trackers and tracking methods do not make it possible to focus and/or orient as optimally as possible, at any time of day and whatever the season, rays from the sun on the photovoltaic cells of a CPV solar collector module.

There is therefore a need to improve the tracking of the trajectory of the sun by a tracker on which a solar collector incorporating one or more CPV modules is mounted, with a view to focusing and/or orienting, as optimally as possible, the rays from the sun on each of the CPV modules, at any time of day and whatever the season.

There is a particular need to provide a simple solution for implementing and reliably improving the tracking of the trajectory of the sun by a tracker on which a solar collector incorporating one or more CPV modules is mounted.

### SUMMARY OF THE INVENTION

To do this, the invention relates, under one of its aspects, to a solar collector module, for a concentrated photovoltaic (CPV) solar plant, comprising a first lens, called the primary lens, consisting of a Fresnel lens, at least one second lens, called the secondary lens, that is right-frustoconical or right-frustopyramidal shaped and arranged below the primary lens, and at least one photovoltaic cell arranged below a secondary lens in order to receive the solar rays concentrated by the primary lens and said secondary lens, the collector module furthermore comprising temperature sensors for measuring temperature differences between a reference temperature and at least four points regularly distributed about the axis connecting the center of the bases of the frustocone or frustopyramid of a secondary lens in order to produce its thermal map.

In other words, according to the invention, by virtue of the temperature sensors local heating of a portion of one wall of the secondary lens is detected relative to other portions of other walls of the secondary lens, this local heating resulting from incorrect focus and/or orientation of the flux of solar rays on the secondary lens.

In other words, simultaneously measuring the temperature of at least four points regularly distributed over the secondary lens, for a given length of time, makes it possible to determine, in real time and with precision, whether the focal point of the primary lens is poorly positioned on the secondary lens, the direction of movement of this misalignment, and, if necessary, the proportion of incident rays that are striking the secondary lens, especially because of defects in the primary lens.

Knowing these two parameters, it is advantageously possible, on the one hand, to carry out fine mechanical adjustments on the positions of the various CPV modules during the phase of fitting the CPV modules on a tracker rack, and, on the other hand, to correct, if required, and at any moment while the CPV collector is generating electricity, any tracker control system implementing a method using astronomical calculations based on theoretical ephemerides. Thus, by virtue of the invention, the flux of solar rays may be optimally focused on the CPV cells of CPV solar collector modules, and, as a result, the efficiency with which said modules generate electricity is improved.

According to one preferred variant, the temperature sensors are each fastened to one face of one wall of the secondary lens. Preferably, the temperature sensors are each fastened to the face of one wall of the secondary lens, said face being opposite the face that receives the solar rays concentrated by the primary lens.

Advantageously, the module comprises four temperature sensors distributed in a group arranged in a plane at equal distance from the bases of the frustocone or frustopyramid of the secondary lens.

According to one advantageous variant, at least eight temperature sensors may be provided, said sensors being distributed in at least two groups each arranged in a plane parallel to the bases of the frustocone or frustopyramid of the secondary lens.

According to one embodiment, the lens is right-frustopyramidal shaped, each temperature sensor being arranged on the axis of symmetry of the trapezoid formed by one of the faces.

Preferably, the temperature sensors are thermocouples or resistance thermometer probes, such as platinum resistance probes, each of which is fastened, by at least one fastening means made of a thermally conductive material, to one face of one wall of the secondary lens. The one or more fastening means may consist of an adhesive, a solder joint or a brazed joint. Temperature measurements are reliably obtained using inexpensive measuring means.

According to one first variant embodiment, the primary lens and the secondary lens are fixedly mounted one relative to the other.

According to a second variant that is an alternative to the first variant, the primary lens and the secondary lens are movably mounted one relative to the other.

The invention relates, under another of its aspects, to a device forming the payload of a CPV solar tracker, comprising a supporting means and at least two solar collector modules, at least one of which is as described above, said modules being mounted on a supporting means itself pivotably mounted about at least one axis in order to track the sun in at least one of the angles chosen from its elevation and azimuth angles relative to the Earth, and at least one actuator for making the supporting means pivot about at least said axis.

According to one variant embodiment, each collector module mounted on the supporting means is as described above, and the payload comprises temperature sensors in order to produce the thermal map of the two secondary lenses that are furthest from each other in each module.

According to another alternative variant embodiment, the payload comprises two collector modules mounted on the supporting means, said modules being as described above and each comprising temperature sensors in order to produce the thermal map of the two secondary lenses that are furthest from each other in the payload.

According to one variant embodiment, the means supporting the payload is rotatable about two separate axes in order to track the sun both in its elevation and azimuth angles relative to the Earth.

According to another alternative variant embodiment, the means supporting the payload pivots about a single axis in order to track the sun in one of the angles chosen from its elevation and azimuth angles relative to the Earth, the other of the angles chosen from the elevation and azimuth angles of the sun being tracked by moving the primary lens relative to the secondary lens(es).

The invention relates, under another of its aspects, to a concentrated photovoltaic (CPV) solar plant, comprising at least one payload as above, and a control unit for controlling each actuator.

Lastly, the invention relates, under another of its aspects, to a method for controlling the control unit of a concentrated photovoltaic solar plant such as described above, comprising the following steps:
a/ measuring temperature differences at four points of at least one secondary lens;
b1/ calculating a first subtraction of the temperature differences measured at two points facing each other and comparing the result with a threshold value;
c1/ when the calculated first subtraction is higher than the threshold value, determining a first angular correction for one of the angles chosen from the elevation and azimuth angles relative to the Earth;
d1/ correcting the pivot angle of the means supporting the collector or moving the primary lens relative to the secondary lens(es) depending on the first angular correction;

b2/ calculating a second subtraction of the temperature differences measured at the two other points facing each other and comparing the result with the threshold value;

c2/ when the calculated second subtraction is higher than the threshold value, determining a second angular correction for the other of the angles chosen from the elevation and azimuth angles relative to the Earth;

d2/ correcting the pivot angle of the means supporting the collector or moving the primary lens relative to the secondary lens(es) depending on the second angular correction;

e/ verifying the effectiveness of the corrections by measuring two temperature subtractions according to steps b1/ and b2/ and verifying the temperature drop obtained; and

f/ if the corrections are deemed to have been ineffective, then repeating steps d1/ and/or d2/ and e/, if not repeating step a/.

Preferably, the method comprises a step e′/ consisting in measuring the electrical power delivered by each CPV solar collector module and in comparing said measured power with the maximum electrical power able to be delivered by the module. This step e′/ is an optional measuring step that consists in advantageously verifying that the amount of electricity generated increases proportionally to the decrease in thermal dispersion.

Preferably, step e/ takes place a few seconds after step d1/ and/or d2/. Thus the corrections may be carried out almost in real time.

Again preferably, the measurements in step a/ are zeroed once per day. This makes it possible to factor out ageing of the temperature sensors, more particularly of the thermocouples, i.e. to factor out any measurement drift that may be different between the thermocouples.

The threshold value is advantageously lower than or equal to 4° C. and typically from 3 to 7° C. This threshold value in practice corresponds to the precision of conventional temperature sensors such as thermocouples.

### DETAILED DESCRIPTION

Other advantages and features of the invention will become more clearly apparent on reading the detailed description of example embodiments thereof, given by way of nonlimiting illustration and with reference to the following figures, in which:

FIG. 1 is a schematic cross-sectional view of a CPV solar collector module according to the prior art, illustrating the relative arrangement of its various components and relative to the sun;

FIG. 1A is an exploded view showing a secondary lens and a photovoltaic cell of a module according to FIG. 1;

FIG. 2 is a schematic side view of a payload incorporating a plurality of CPV modules and mounted on a prior-art tracker;

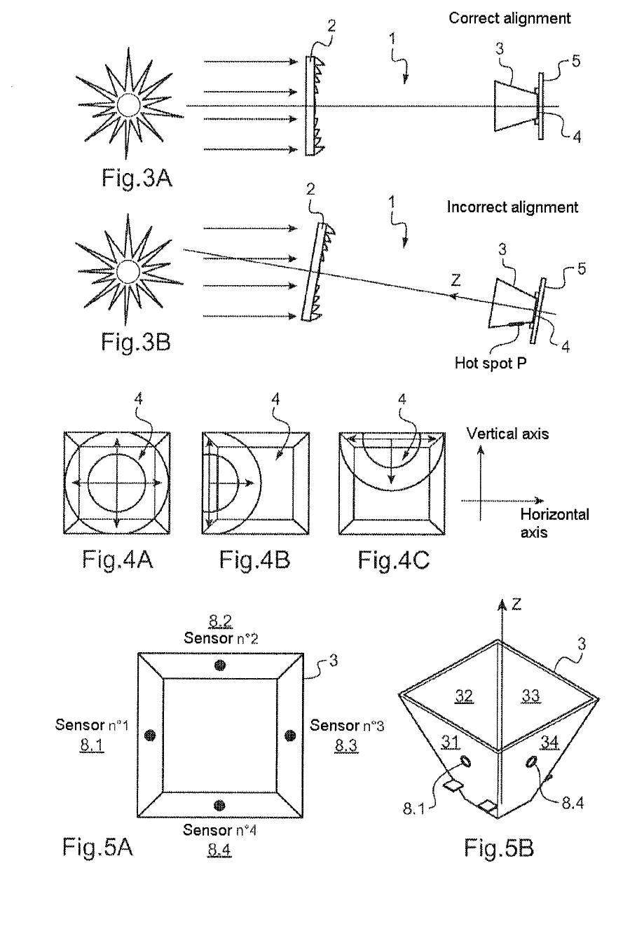

FIGS. 3A and 3B are schematic cross-sectional views of one portion of a CPV solar collector module according to the prior art, illustrating the relative arrangement of these various components and relative to the sun, in a correctly and incorrectly aligned configuration, respectively;

FIGS. 4A to 4C are schematic top views of a secondary lens arranged above a photovoltaic cell of a CPV module, showing the focal spot of the sun in a configuration that is correctly aligned relative to the sun, in a configuration that is incorrectly aligned with respect to the azimuth angle of the sun, and in a configuration that is incorrectly aligned with respect to the elevation angle of the sun, respectively;

FIGS. 5A and 5B are top and perspective views, respectively, of a secondary lens of a CPV module comprising temperature sensors according to the invention;

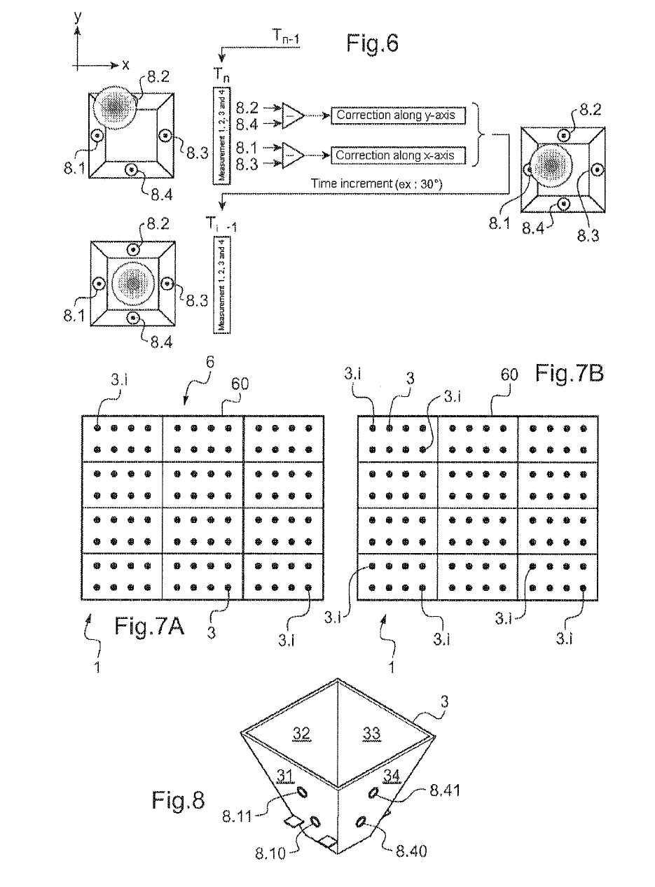

FIG. 6 illustrates the steps of a method for controlling a CPV solar collector module according to the invention, allowing it to pass from an incorrectly aligned configuration to a correctly aligned configuration;

FIGS. 7A and 7B illustrate two different variants of the arrangement of the temperature sensors in a solar collector incorporating a plurality of CPV modules according to one embodiment of the invention; and

FIG. 8 is a perspective view of a secondary lens of a CPV module comprising temperature sensors according to one variant of the invention.

For the sake of clarity, given references designating given elements of the CPV solar collector module according to the prior art and of the CPV solar collector module according to the invention are used in all the FIGS. 1 to 7B.

It will be noted that the various elements, in particular the primary and secondary lenses according to the invention, are shown merely for the sake of clarity and they are not to scale.

FIGS. 1, 1A and 2, which relate to a CPV solar collector module according to the prior art, have already been commented on in the preamble. They are not described in detail here.

FIG. 3A shows a configuration in which a CPV solar collector module 1 is perfectly aligned relative to the sun. The rays from the sun are perfectly orthogonal to the surface of the primary lens 2. The rays are therefore perfectly concentrated on the secondary lens 3 by means of the primary lens 2, the secondary lens 3 then directing the light from the sun centrally onto the photovoltaic cell 4. Schematically, the focal spot of the sun is thus perfectly centered on the photovoltaic cell 4 (FIG. 4A).

However, this correct alignment configuration is almost never achieved. This may be for a number of reasons including the drawbacks of the methods implemented in trackers, possible variations in the dimensions and assembly of the components of a CPV module, the sensitivity of the measurement sensors used in the tracking methods, variation in the assembly and its components over time (warp especially), etc.

Thus, in general, a CPV collector module will be incorrectly aligned relative to the sun. The rays from the sun are therefore not perfectly orthogonal to the surface of the primary lens 2 and thus they are therefore not perfectly concentrated on the secondary lens 3 (FIG. 3B). In other words, the focus of the primary lens 2 is imperfect. Schematically, the focal spot of the sun is thus miscentered relative to the center of the photovoltaic cell: depending on the direction of the focal shift, the focal spot is shifted over the cell 4. An azimuthal focal shift for example results in a right/left asymmetry in the focal spot on the cell 4 (FIG. 4B), whereas an elevational focal shift results in a front/back asymmetry in the focal spot on the cell 4 (FIG. 4C). As schematically symbolized to the right of FIGS. 4A to 4C, a right/left asymmetry is an asymmetry along the horizontal axis relative to the Earth's surface whereas a front/back asymmetry is an asymmetry along the vertical axis relative to the Earth's surface.

Thus, any asymmetry results in the creation of a hot spot P, or in other words in local heating of the secondary lens (FIG. 3B). In other words, a configuration in which a CPV module is incorrectly aligned relative to the sun results in a nonuniform thermal gradient in a cross section of the right-frustopyramidal-shaped secondary lens.

To avoid these incorrect CPV module alignment configurations, the inventors judiciously thought to quantify the thermal gradient in real time in the secondary lens 3, in order to measure, relatively precisely, the position of the focal point of the primary lens 2 and its movement.

Thus, provision is made, according to the invention, to fasten four temperature sensors 8.1, 8.2, 8.3, 8.4 to one face of one wall 31, 32, 33, 34 of the secondary lens 3, i.e. the sensors are regularly distributed at 90° to one another about the Z-axis connecting the center of the bases of the frustopyramid representing the secondary lens.

The temperature sensors may be thermocouples or resistance thermometer probes, such as platinum probes. Preferably, as schematically shown in FIGS. 5A and 5B, each temperature thermocouple 8.1, 8.2, 8.3, 8.4 is fastened to the center and back face of one trapezoidal-shaped wall 31, 32, 33, 34. This fastening is achieved using an adhesive made of a thermally conductive material. Typically, it may be a question of a polyimide kapton tab covered with a silicone adhesive or a piece of aluminum tape, particularly suitable when the secondary lens is made of aluminum. The size and type of bonding tab is preferably identical for each thermocouple.

By virtue of the four temperature sensors 8.1, 8.2, 8.3, 8.4, it is possible to measure simultaneously the temperature at these four temperature points for a given length of time and thus to establish a thermal map, i.e. to determine the thermal gradient in the secondary lens 3. This makes it possible to determine with precision the position of the focal point of the primary lens 2 and its movement.

It is thus possible, while electricity is being generated by a solar collector incorporating a plurality of CPV modules, to correct (refine) control of the movement of a tracker on which the collector is mounted relative to a control method using astronomical calculations based on ephemerides.

This correction to the control of the movement of the tracker may be made via closed-loop feedback.

By way of an advantageous variant, it may be envisioned to fasten eight temperature sensors distributed in two groups each arranged in a plane parallel to the bases of the frustopyramid of the secondary lens.

FIG. 6 shows the various steps of a method for controlling the control unit of a solar collector comprising a plurality of CPV modules having thermocouples 8.1 to 8.4 fastened to their secondary lens 3 according to the invention. This control corresponds to correction of the movement of the tracker along the two axes x and y corresponding to the elevation and azimuth angles of the sun. Specifically, the focal spot is shown initially shifted both to the left and top of the photovoltaic cell 4.

Step a/: simultaneously measuring temperature differences by virtue of each of the four sensors 8.1 to 8.4;

Step b1/: calculating a first subtraction of temperature differences measured with the two sensors 8.2 and 8.4 and comparing the result to a threshold value. Typically the threshold value is equal to 4° C.;

Step c1/: determining a first angular correction along the y-axis;

Step d1/: correcting the pivot angle of the means supporting the CPV collector depending on the first angular correction along the y-axis;

Step b2/: calculating a second subtraction of temperature differences measured with the two other sensors 8.1 and 8.3 and comparing the result to the threshold value;

Step c2/: determining a second angular correction along the x-axis;

Step d2/: correcting the pivot angle of the means supporting the collector depending on the second angular correction.

Preferably, steps d1/ and d2/ are carried out simultaneously.

Step e/: verifying the effectiveness of the corrections by measuring two temperature subtractions according to steps b1/ and b2/ and verifying the temperature drop obtained.

Step e′: verifying the effectiveness of the corrections by measuring the electrical power delivered by a CPV module and comparing this to its maximum electrical power.

Step f: repeating step a/. In the embodiment in FIG. 6, a time increment of about thirty seconds is left between the correcting steps d1/ and d2/ and the new step a/. This increment is given by way of indication insofar as a larger time increment is also possible.

Thus, according to the invention, the position of the focal point of the primary lens 2 is therefore related to the subtractions carried out in steps b1/ and b2/: the absolute value and the sign of these two subtractions is used in the tracker control unit.

Advantageously, it may be envisioned to zero the temperature measurements on each day on which electricity is generated. This makes it possible to factor out any ageing of temperature sensors, such as the thermocouples, which may induce a different measurement drift in the thermocouples 8.1 to 8.4.

FIGS. 7A and 7B show two separate variant arrangements of temperature sensors according to the invention in a solar collector comprising twelve CPV modules incorporated on one and the same supporting means 60, called a rack. The references 3.i designate secondary lenses equipped with temperature sensors according to the invention whereas the references 3 designate known secondary lenses, i.e. lenses without temperature sensors.

For a CPV solar collector the dimensions and assembly of which are subject to strict tolerances and quality control, it may be envisioned to arrange temperature sensors in order to produce the thermal map of the two secondary lenses 3.i furthest from each other on the rack 60 of the collector (FIG. 7A).

To make fine adjustments to the CPV modules after they have been fitted on the rack 60, and to position the collector more precisely relative to the sun, provision may advantageously be made for each module 1 to comprise temperature sensors in order to produce the thermal map of the two secondary lenses 3.1 furthest from each other in each module (FIG. 7B).

The expression “comprising a” must be understood as being synonymous with “comprising at least one” unless otherwise specified.

The invention is not limited to the examples described above; in particular features of the illustrated examples may be combined together in variants that are not illustrated.

Other improvements or variants may be made without departing from the scope of the invention.

Thus, it may advantageously be envisioned to implant eight temperature sensors distributed in two groups each arranged in a plane parallel to the bases of the frustopyramid of the secondary lens, as partially shown in FIG. 8, in which the sensors of one group 8.10, 8.40 are arranged under the sensors 8.11, 8.41 of the other group and parallel to the bases of the secondary lens 3.

The expression “comprising a” must be understood as being synonymous with “comprising at least one” unless otherwise specified.

1. A solar collector module, for a concentrated photovoltaic (CPV) solar plant, comprising a first lens, called the primary lens, consisting of a Fresnel lens, at least one second lens, called the secondary lens, that is right-frustoconical or right-frustopyramidal shaped and arranged below the primary lens, and at least one photovoltaic cell arranged below a secondary lens in order to receive the solar rays concentrated by the primary lens and said secondary lens, the collector module furthermore comprising temperature sensors for measuring temperature differences between a reference temperature and at least four points regularly distributed about the axis connecting the center of the bases of the frustocone or frustopyramid of a secondary lens in order to produce its thermal map.

2. The solar collector module as claimed in claim 1, in which the temperature sensors are each fastened to one face of one wall of the secondary lens.

3. The solar collector module as claimed in claim 2, in which the temperature sensors are each fastened to the face of one wall of the secondary lens, said face being opposite the face that receives the solar rays concentrated by the primary lens.

4. The solar collector module as claimed in claim 2, comprising four temperature sensors distributed in a group arranged in a plane at equal distance from the bases of the frustocone or frustopyramid of the secondary lens.

5. The solar collector module as claimed in claim 2, comprising at least eight temperature sensors distributed in at least two groups each arranged in a plane parallel to the bases of the frustocone or frustopyramid of the secondary lens.

6. The solar collector module as claimed in claim 4, the lens being right-frustopyramidal shaped, each temperature sensor being arranged on the axis of symmetry of the trapezoid formed by one of the faces.

7. The solar collector module as claimed in claim 4, the temperature sensors being thermocouples or resistance thermometer probes, each of which is fastened, by at least one fastening means made of a thermally conductive material, to one face of one wall of the secondary lens.

8. The solar collector module as claimed in claim 7, the one or more fastening means consisting of an adhesive, a solder joint or a brazed joint.

9. The solar collector module as claimed in claim 1, the primary lens and the secondary lens being fixedly mounted one relative to the other.

10. The solar collector module as claimed in claim 1, the primary lens and the secondary lens being movably mounted one relative to the other.

11. A device forming the payload of a CPV solar tracker, comprising a supporting means and at least two solar collector modules, at least one of which is as claimed in claim 1, said modules being mounted on a supporting means itself pivotably mounted about at least one axis in order to track the sun in at least one of the angles chosen from its elevation and azimuth angles relative to the Earth, and at least one actuator for making the supporting means pivot about at least said axis.

12. The payload as claimed in claim 11, each collector module mounted on the supporting means and comprising temperature sensors in order to produce the thermal map of the two secondary lenses that are furthest from each other in each module.

13. The payload as claimed in claim 11, comprising two of the collector modules mounted on the supporting means, each comprising temperature sensors in order to produce the thermal map of the two secondary lenses that are furthest from each other in the payload.

14. The payload as claimed in claim 11, the means supporting the payload being rotatable about two separate axes in order to track the sun both in its elevation and azimuth angles relative to the Earth.

15. The payload as claimed in claim 11, the means supporting the payload pivoting about a single axis in order to track the sun in one of the angles chosen from its elevation and azimuth angles relative to the Earth, the other of the angles chosen from the elevation and azimuth angles of the sun being tracked by moving the primary lens relative to the secondary lens(es).

16. A concentrated photovoltaic (CPV) solar plant, comprising at least one payload as claimed in claim 11, and a control unit for controlling each actuator.

17. A method for controlling the control unit of a concentrated photovoltaic solar plant as claimed in claim 16, comprising the following steps:
a/ measuring temperature differences at four points of at least one secondary lens;
b1/ calculating a first subtraction of the temperature differences measured at two points facing each other and comparing the result with a threshold value;
c1/ when the calculated first subtraction is higher than the threshold value, determining a first angular correction for one of the angles chosen from the elevation and azimuth angles relative to the Earth;
d1/ correcting the pivot angle of the means supporting the collector or moving the primary lens relative to the secondary lens(es) depending on the first angular correction;
b2/ calculating a second subtraction of the temperature differences measured at the two other points facing each other and comparing the result with the threshold value;
c2/ when the calculated second subtraction is higher than the threshold value, determining a second angular correction for the other of the angles chosen from the elevation and azimuth angles relative to the Earth;
d2/ correcting the pivot angle of the means supporting the collector or moving the primary lens relative to the secondary lens(es) depending on the second angular correction;
e/ verifying the effectiveness of the corrections by measuring two temperature subtractions according to steps b1/ and b2/ and verifying the temperature drop obtained; and
f/ if the corrections are deemed to have been ineffective, then repeating steps d1/ and/or d2/ and e/, if not repeating step a/.

18. The control method as claimed in claim 17, comprising a step e′/ consisting in measuring the electrical power delivered by each CPV solar collector module and in comparing said measured power with the maximum electrical power able to be delivered by the module.

19. The control method as claimed in claim 17, in which step e/ takes place a few seconds after step d1/ and/or d2/.

20. The control method as claimed in claim 17, in which the measurements in step a/ are zeroed once per day.

21. The control method as claimed in claim 17, in which the threshold value is lower than or equal to 4° C.
